(19) United States
(12) Patent Application Publication
(10) Pub. No.: US 2014/0097419 A1
(43) Pub. Date: Apr. 10, 2014

(54) ORGANIC LIGHT EMITTING DIODE DISPLAY AND METHOD FOR MANUFACTURING THE SAME

(71) Applicants: Young-Dae KIM, Yongin-City (KR); Jong-Yun KIM, Yongin-City (KR)

(72) Inventors: Young-Dae KIM, Yongin-City (KR); Jong-Yun KIM, Yongin-City (KR)

(21) Appl. No.: 13/960,221

(22) Filed: Aug. 6, 2013

(30) Foreign Application Priority Data
Oct. 4, 2012 (KR) 10-2012-0110086

(51) Int. Cl. H01L 27/32; H01L 51/56

(52) U.S. Cl. CPC H01L 27/3244; H01L 51/56
USPC 257/40; 438/46

(57) ABSTRACT

An organic light emitting diode (OLED) display includes a substrate, a first signal line on the substrate, a first thin film transistor connected to the first signal line, a second thin film transistor connected to the first thin film transistor, an interlayer insulating layer on the first thin film transistor and the second thin film transistor, a second signal line on the interlayer insulating layer and connected to a source electrode of the first thin film transistor, a third signal line on the interlayer insulating layer and connected to a source electrode of the second thin film transistor, a first electrode on the interlayer insulating layer and connected to a drain electrode of the second thin film transistor, an organic emission layer on the first electrode, and a second electrode placed on the organic emission layer, wherein the third signal line and the first electrode are made of different metals.

### RELATED APPLICATIONS

This application claims priority under 35 U.S.C. §119 to and the benefit of Korean Patent Application No. 10-2012-0110086 filed in the Korean Intellectual Property Office on Oct. 4, 2012, the entire contents of which are incorporated herein by reference.

### BACKGROUND

1. Field

The described technology relates generally to an organic light emitting diode (OLED) display and a method of manufacturing the same.

2. Description of the Related Art

An organic light emitting diode (OLED) display is a self emitting type display device that displays an image using organic light emitting diodes for emitting light. The organic light emitting diode (OLED) display can reduce a thickness and weight relatively because it does not need an additional light source unlike a liquid crystal display (LCD). Furthermore, the organic light emitting diode (OLED) display has been in the spotlight as the next-generation display device of a portable electronic device because it has several advantages, e.g., low power consumption, high luminance, and a high reaction speed.

Organic light emitting diode (OLED) displays are divided into a passive matrix type and an active matrix type depending on its driving method. An active matrix type organic light emitting diode (OLED) display includes an organic light emitting diode, as well as a thin film transistor (TFT) and a capacitor for each pixel, and independently controls the pixels. This organic light emitting diode (OLED) display can be divided into front light emission and rear light emission depending on a direction where light is emitted.

In the case of front light emission, the anode electrode of an organic light emitting diode and a data line are formed in the same layer in order to reduce a mask process. Here, the anode electrode requires a material having excellent reflectance, while the data line requires a material having low resistance and a corrosion-resistant property. However, materials having excellent reflectance, e.g., silver, are not corrosion resistant, while materials that are corrosion resistance, e.g., titanium, have low reflectance.

The above information disclosed in this Background section is only for enhancement of understanding of the background of the described technology and therefore it may contain information that does not form the prior art that is already known in this country to a person of ordinary skill in the art.

### SUMMARY

According to an embodiment, an organic light emitting diode (OLED) display includes a substrate, a first signal line on substrate, a first thin film transistor connected to the first signal line, a second thin film transistor connected to the first thin film transistor, an interlayer insulating layer on the first thin film transistor and the second thin film transistor, a second signal line on the interlayer insulating layer and connected to a source electrode of the first thin film transistor, a third signal line on the interlayer insulating layer and connected to a source electrode of the second thin film transistor, a first electrode on the interlayer insulating layer and connected to a drain electrode of the second thin film transistor, an organic emission layer on the first electrode, and a second electrode on the organic emission layer, wherein the third signal line and the first electrode are made of different metals.

The third signal line may be made of the same material as the source electrode of the second thin film transistor, and the drain electrode of the second thin film transistor and the first electrode may be made of the same material.

The third signal line may be integrally formed with the source electrode of the second thin film transistor and connected to a semiconductor of the second thin film transistor through a contact hole of the interlayer insulating layer, and the drain electrode of the second thin film transistor may be integrally formed with the first electrode and connected to the semiconductor of the second thin film transistor through the contact hole of the interlayer insulating layer.

The third signal line may include metal having lower resistance than the first electrode, and the first electrode may include metal having higher reflectance than the third signal line.

The metal having lower resistance may include at least one of aluminum, titanium, molybdenum, and an alloy of them, and the metal having higher reflectance may be silver.

The third signal line may include titanium, aluminum, and titanium, and the first electrode may include ITO, Ag, and ITO.

The organic light emitting diode (OLED) display may further include a dummy pattern placed over the interlayer insulating layer, extended in a direction to intersect the second signal line, and separated from the second signal line and the third signal line.

The dummy pattern may be made of the same material as the second signal line and the third signal line.

A distance between the dummy pattern, the second signal line, the third signal line, the source electrode and drain electrode of the first thin film transistor, the source electrode of the second thin film transistor, and the first electrode may be smaller than a distance between the dummy pattern, the second signal line, the third signal line, the source electrode and drain electrode of the first thin film transistor, and the source electrode of the second thin film transistor.

According to another embodiment, a method of manufacturing an organic light emitting diode (OLED) display includes forming a first signal line on a substrate, forming a thin film transistor connected to the first signal line, forming an interlayer insulating layer on the thin film transistor, forming a first metal film over the interlayer insulating layer, forming photoresist patterns, each including a first part configured to have a first width and a second part placed on the first part and configured to have a second width wider than the first width of the first part, over the first metal film, forming a second signal line by etching the first metal film using the photoresist patterns as a mask, forming a second metal film over the photoresist patterns and the interlayer insulating layer and then forming a first electrode on the interlayer insulating layer, forming an organic emission layer on the first electrode, and forming a second electrode on the organic emission layer.

The first part and the second part may be made of different photoresist materials.

Forming the photoresist patterns may include stacking a first photoresist film and a second photoresist film, having different development speeds, over the first metal film and developing the first photoresist film and the second photoresist film.

The development speed of the first photoresist film may be faster than the development speed of the second photoresist film.

Forming the photoresist patterns may include forming a photoresist film on the first metal film using a negative photoresist material and exposing the photoresist film using the photoresist film by a half-tone mask and then developing the photoresist film.

Forming the first electrode may include forming a second metal film over the photoresist patterns and the interlayer insulating layer and then removing the photoresist patterns using a lift-off method.

### BRIEF DESCRIPTION OF THE DRAWINGS

FIG. 1 is a diagram showing a display device constructed with the principle in accordance with an exemplary embodiment.

FIG. 2 is a layout view of one pixel of the organic light emitting diode (OLED) display of FIG. 1.

FIG. 3 is a cross-sectional view taken along line of FIG. 2.

FIGS. 4 to 17 are diagrams showing stages in a method of manufacturing the organic light emitting diode (OLED) display in accordance with an exemplary embodiment.

### DETAILED DESCRIPTION

Exemplary embodiments will be described more fully hereinafter with reference to the accompanying drawings. As those skilled in the art would realize, the described embodiments may be modified in various different ways, all without departing from the spirit or scope of the present disclosure.

In the drawings, the thickness of layers, films, panels, regions, etc., are exaggerated for clarity. Like reference numerals designate like elements throughout the specification. It will be understood that when an element such as a layer, film, region, or the substrate is referred to as being “on” another element, it can be directly on the other element or intervening elements may also be present. In contrast, when an element is referred to as being “directly on” another element, there are no intervening elements present.

An organic light emitting diode (OLED) display in accordance with an exemplary embodiment is described in detail below with reference to the drawings.

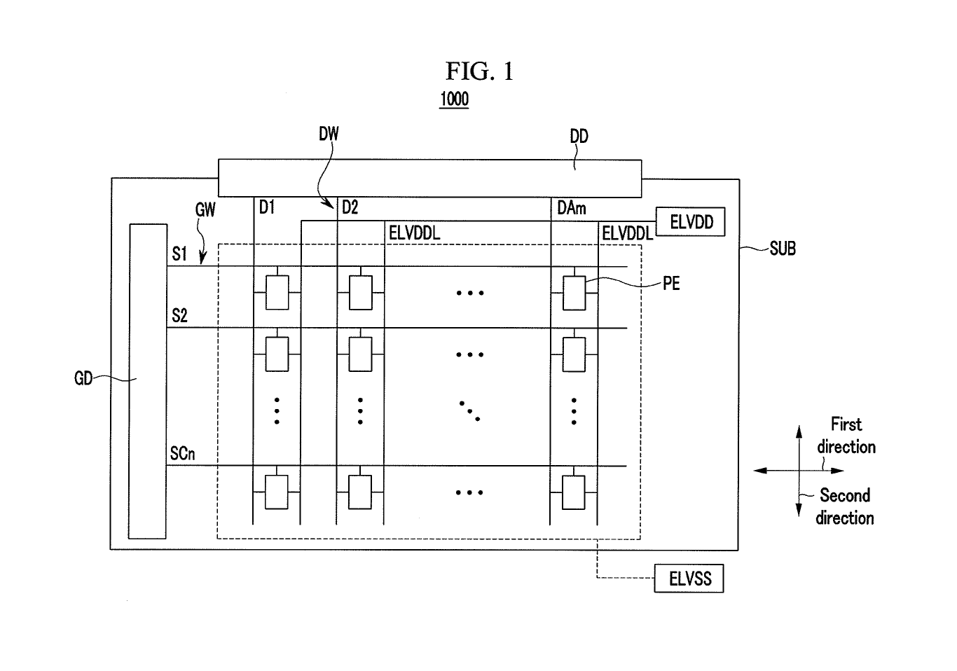

FIG. 1 is a diagram showing a display device constructed with the principle in accordance with an exemplary embodiment.

As illustrated in FIG. 1, a display device 1000 constructed with the principle of the first embodiment of the present invention includes a substrate SUB, a gate driver GD, gate wires GW, a data driver DD, data wires DW, and pixels PE. Here, the pixel

PE means a minimum unit displaying an image, and the display device 1000 displays the image through a plurality of pixels PE.

The substrate SUB is formed by a transparent insulating substrate made of glass, quartz, ceramic, plastic, and the like. However, the first embodiment of the present invention is not limited thereto, and the substrate SUB may be formed by a metallic substrate made of stainless steel and the like. Further, in the case where the substrate SUB is made of plastic and the like, the display device 1000 may have a flexible characteristic and a stretchable or rollable characteristic.

The gate driver GD sequentially supplies scan signals to the gate wires GW in response to a control signal supplied from an external control circuit (not illustrated), for example, a timing controller. Then, the pixels PE are selected by the scan signal to sequentially receive data signals.

The gate wires GW are positioned on the substrate SUB and extend in a first direction. The gate wires GW include scan lines S1-SCn, and the scan line SCn is connected with the gate driver GD to receive the scan signal from the gate driver GD.

Meanwhile, in the display device 1000 constructed with the principle of the first embodiment of the present invention, the gate wires GW include the scan line SCn; however, in a display device according to another embodiment, the gate wires may further include an additional scan line, an initial power supply line, a light emission control line and the like. In this case, the display device may be an active matrix (AM) organic light emitting diode display device having a 6Tr-2Cap structure.

The data driver DD supplies a data signal to a data line DAm among the data wires DW in response to a control signal supplied from the outside of the timing controller and the like. The data signal supplied to the data line DAm is supplied to the pixel PE selected by the scan signal whenever the scan signal is supplied to the scan line SCn. Then, the pixel PE charges a voltage corresponding to the data signal to emit light at luminance corresponding thereto.

The data wires DW may be positioned on the gate wires GW, or positioned between the gate wires GW and the substrate SUB, and extends in a second direction crossing the first direction. The data wires DW include data lines D1-Dm and a driving power supply line ELVDDL. The data line DAm is connected with the data driver DD and receives a data signal from the data driver DD. The driving power supply line ELVDDL is connected with an external first power supply ELVDD and receives a driving power supply from the first power supply ELVDD.

The pixel PE is positioned in a region where the gate wires GW and the data wires DW cross each other to be connected with the gate wires GW and the data wires DW. The pixel PE includes a first power supply ELVDD, two thin film transistors and capacitors connected with the gate wires GW and the data wires DW, and an organic light emitting diode connected with a second power supply ELVSS with a thin film transistor therebetween. The pixel PE is selected when the scan signal is supplied through the scan line SCn to charge a voltage corresponding to the data signal through the data line DAm and emits light having predetermined luminance in response to the charged voltage. A detailed layout of the pixel PE will be described below.

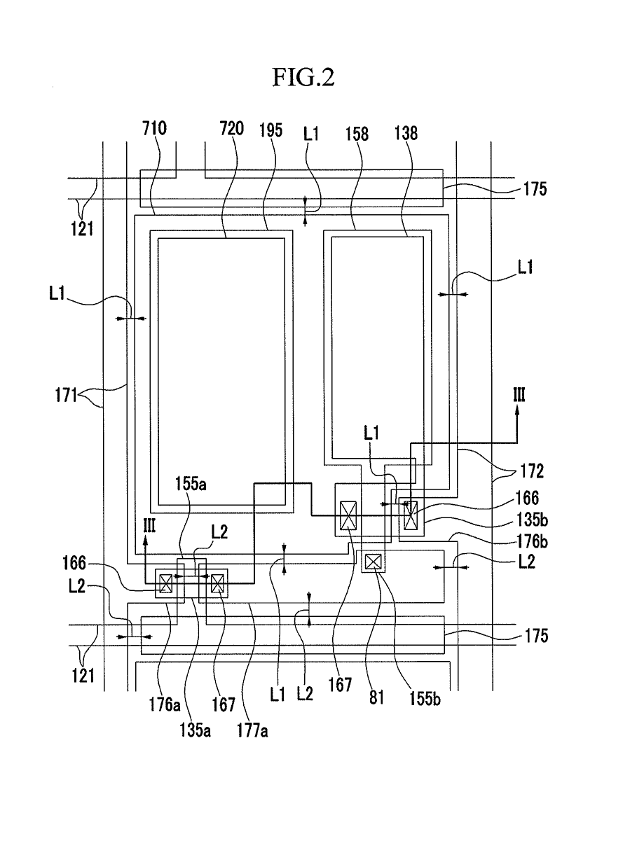

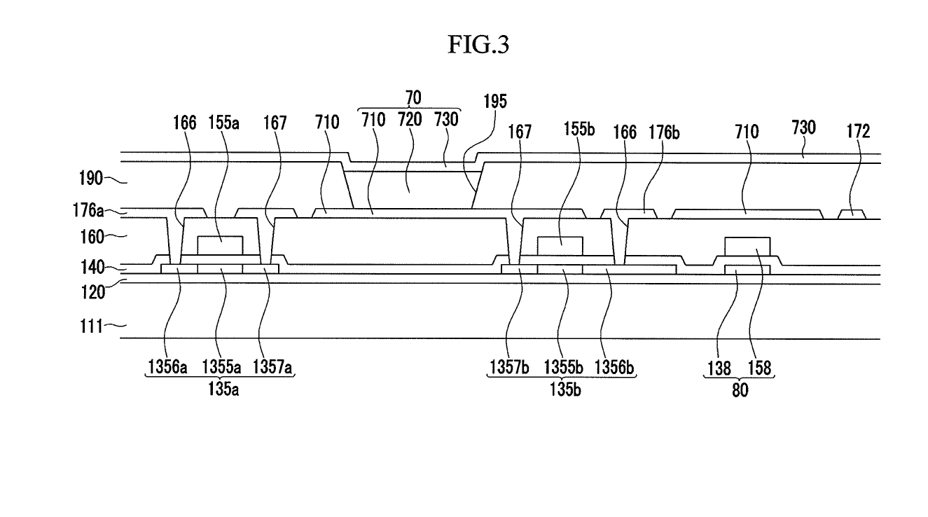

The organic light emitting diode (OLED) display in accordance with an exemplary embodiment is described in detail below with reference to FIGS. 2 and 3. FIG. 2 is a layout view of one pixel of the organic light emitting diode (OLED) display of FIG. 1. FIG. 3 is a cross-sectional view taken along line of FIG. 2.

As shown in FIGS. 2 and 3, a buffer layer 120 is formed on a substrate 111. The substrate 111 can be an insulating substrate, e.g., glass, quartz, ceramic, or plastic, or can be a metallic substrate, e.g., stainless steel.

The buffer layer 120 can be formed to have a single film made of silicon nitride (SiNx) or a dual film structure in which silicon nitride (SiNx) and silicon oxide (SiO₂) are stacked. The buffer layer 120 functions to prevent the infiltration of unnecessary components, such as impurities or moisture, and also make provide a flat surface.

A first semiconductor 135a and a second semiconductor 135b, both made of polysilicon, and a first capacitor electrode 138 are formed on the buffer layer 120.

The first semiconductor 135a and the second semiconductor 135b are divided into respective channel regions 1355a and 1355b, with source regions 1356a and 1356b and drain regions 1357a and 1357b, respectively, formed on both sides of the channel regions 1355a and 1355b. The channel regions 1355a and 1355b of the first semiconductor 135a and the second semiconductor 135b are polysilicon into which impurities have not been doped, i.e., intrinsic semiconductors. The source regions 1356a and 1356b and the drain regions 1357a and 1357b of the first semiconductor 135a and the second semiconductor 135b are polysilicon into which conductive impurities have been doped, i.e., impurity semiconductors. The impurities dopes into the source regions 1356a and 1356b, the drain regions 1357a and 1357b, and the first capacitor electrode 138 can be either p-type impurities and n-type impurities.

A gate insulating layer 140 is formed on the first semiconductor 135a, the second semiconductor 135b, and the first capacitor electrode 138. The gate insulating layer 140 can be a single layer or a plurality of layers including at least one of tetra ethyl ortho silicate (TEOS), silicon nitride (SiNx), and silicon oxide (SiO₂).

A gate line 121, a second gate electrode 155b, and a second capacitor electrode 158 are formed on the gate insulating layer 140. The gate line 121 extends lengthwise in a horizontal direction and transfers a gate signal. The gate line 121 includes a first gate electrode 155a that protrudes from the gate line 121 to the first semiconductor 135a.

The first gate electrode 155a and the second gate electrode 155b overlap the respective channel regions 1355a and 1355b, and the second capacitor electrode 158 overlaps the first capacitor electrode 138. Each of the second capacitor electrode 158, the first gate electrode 155a, and the second gate electrode 155b can have a single layer or a plurality of layers made of, e.g., molybdenum, tungsten, copper, aluminum, or an alloy thereof.

The first capacitor electrode 138 and the second capacitor electrode 158 form a capacitor 80 using the gate insulating layer 140 as a dielectric material.

An interlayer insulating layer 160 is formed on the first gate electrode 155a, the second gate electrode 155b, and the second capacitor electrode 158. The interlayer insulating layer 160, like the gate insulating layer 140, can be made of tetra ethyl ortho silicate (TEOS), silicon nitride (SiNx), or silicon oxide (SiO₂).

The interlayer insulating layer 160 and the gate insulating layer 140 include a source contact hole 166 and a drain contact hole 167 through which the source regions 1356a and 1356b and the drain regions 1357a and 1357b are exposed, respectively.

A data line 171 having a first source electrode 176a, a constant voltage line 172 having a second source electrode 176b, a first drain electrode 177a, a dummy pattern 175, and a first electrode 710 are formed on the interlayer insulating layer 160.

The data line 171 transfers a data signal and extends in a direction to intersect the gate line 121. The constant voltage line 172 transfers a specific voltage. The constant voltage line 172 is separated from the data line 171 and extends in the same direction as the data line 171.

The first source electrode 176a protrudes from the data line 171 to the first semiconductor 135a. The second source electrode 176b protrudes from the constant voltage line 172 to the second semiconductor 135b. The first source electrode 176a and the second source electrode 176b are connected to the respective source regions 1356a and 1356b through the source contact hole 166.

The first drain electrode 177a is configured to face the first source electrode 176a and connected to the drain region 1357a through the contact hole 167. Furthermore, part of the first electrode 710 that faces the second source electrode 176b is a second drain electrode and is connected to the drain region 1357b through the contact hole 167.

The first drain electrode 177a extends along the gate line 121 and electrically connected to the second gate electrode 155b through the contact hole 81. The first electrode 710 can be the anode electrode of the organic light emitting diode shown in FIG. 1 and may be integrally connected to the second drain electrode of the second thin film transistor.

A dummy pattern 175 separates the first electrode 710 into upper and lower directions in terms of a manufacturing process is described in detail later along with a manufacturing process.

Each of the data line 171, the constant voltage line 172, the first drain electrode 177a, and the dummy pattern 175 can have a single layer or a plurality of layers made of a low resistance material or a corrosion-resistant material, e.g., Al, Ti, Mo, Cu, Ni, or an alloy thereof. For example, each of the data line 171, the constant voltage line 172, the first drain electrode 177a, and the dummy pattern 175 can have a triple layer formed of Ti/Cu/Ti or Ti/Ag/Ti.

Furthermore, the first electrode 710 can have a single layer or a plurality of layers made of material having excellent reflectance, such as Ag, or a transparent material, such as ITO. For example, the first electrode 710 can have a triple layer including ITO, Ag, and ITO.

Meanwhile, a first interval L1 between the data line 171, the constant voltage line 172, the first drain electrode 177a, and the dummy pattern 175 and the first electrode 710 can be smaller than a second interval L2 between the data line 171, the constant voltage line 172, the first drain electrode 177a, and the dummy pattern 175.

A pixel definition film 190 is formed on the data line 171, the constant voltage line 172, the first drain electrode 177a, the dummy pattern 175, and the first electrode 710.

The pixel definition film 190 has an opening 195 through which the first electrode 710 is exposed. The pixel definition film 190 can be made of resin, e.g., polyacrylates or polyimides, or a silica-series inorganic substance.

An organic emission layer 720 is formed in the opening 195 of the pixel definition film 190. The organic emission layer 720 is formed of a plurality of layers including one or more of an emission layer, a hole injection layer (HIL), a hole transport layer (HTL), an electron transport layer (ETL), and an electron injection layer (EIL). If the organic emission layer 720 includes all of the emission layer, the HIL, the HTL, the ETL, and the EIL, the HIL is placed on the first electrode 710, i.e., the anode electrode, and the HTL, the emission layer, the ETL, and the EIL can be sequentially stacked over the HIL.

A common electrode 730 is formed on the pixel definition film 190 and the organic emission layer 720. The common electrode 730 becomes the cathode electrode of an organic light emitting diode 70. Accordingly, the first electrode 710, the organic emission layer 720, and the common electrode 730 form the organic light emitting diode 70.

The organic light emitting diode (OLED) display can have any one of a front display type structure, a rear display type structure, and a dual display type structure depending on a direction where the organic light emitting diode 70 emits light.

In the case of the front display type structure, the first electrode 710 is formed of a reflective layer and the common electrode 730 is formed of a reflective layer and a semi-transparent layer. In contrast, in the case of the rear display type structure, the first electrode 710 is formed of a semi-transparent layer and the common electrode 730 is formed of a reflective layer. Furthermore, in the case of the dual display type structure, each of the first electrode 710 and the common electrode 730 is formed of a transparent layer or a semi-transparent layer.

The reflective layer and the semi-transparent layer are made of one or more of magnesium (Mg), silver (Ag), gold (Au), calcium (Ca), lithium (Li), chromium (Cr), and aluminum (Al) or an alloy thereof. The reflective layer and the semi-transparent layer are determined according to their thickness, and the semi-transparent layer can have a thickness of 200 nm or lower. If the thickness is reduced, the transmittance of light is increased. If the thickness is too thin, resistance is increased.

The transparent layer may be made of, e.g., indium tin oxide (ITO), indium zinc oxide (IZO), zinc oxide (ZnO), or indium oxide (In₂O₃).

A method of manufacturing the aforementioned organic light emitting diode (OLED) display is described in detail with reference to FIGS. 4 to 15 and FIGS. 2 and 3.

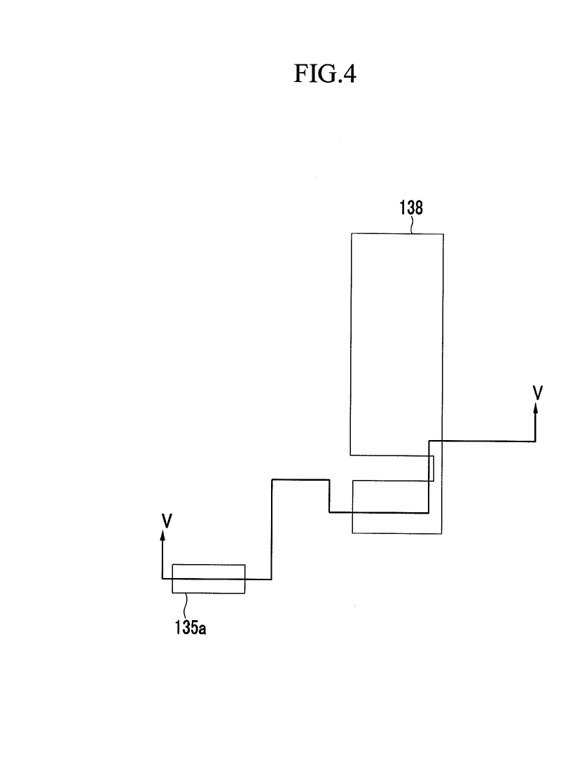

FIGS. 4 to 17 are diagrams showing stages in a method of manufacturing the organic light emitting diode (OLED) display in accordance with an exemplary embodiment.

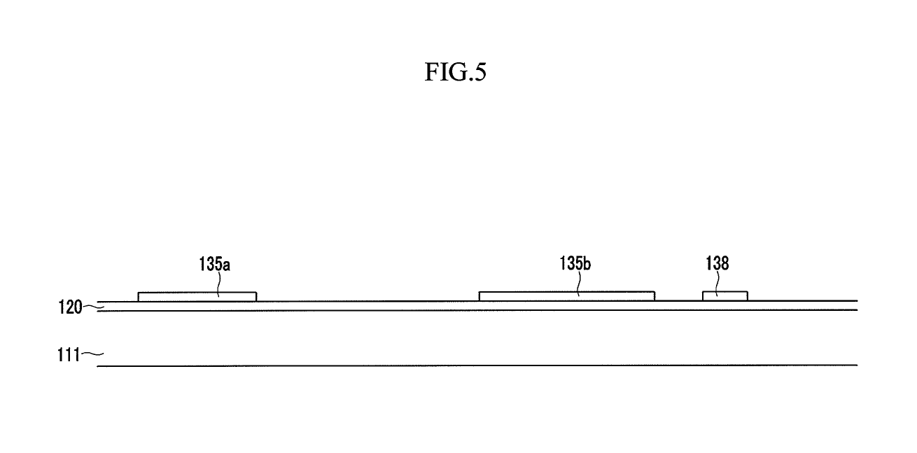

First, as shown in FIGS. 4 and 5, the buffer layer 120 is formed on the substrate 111. The buffer layer 120 can be made of silicon nitride (SiNx) or silicon oxide (SiO₂).

After forming a polysilicon film on the buffer layer 120, the first semiconductor 135a, the second semiconductor 135b, and the first capacitor electrode 138 may be formed by patterning the polysilicon film.

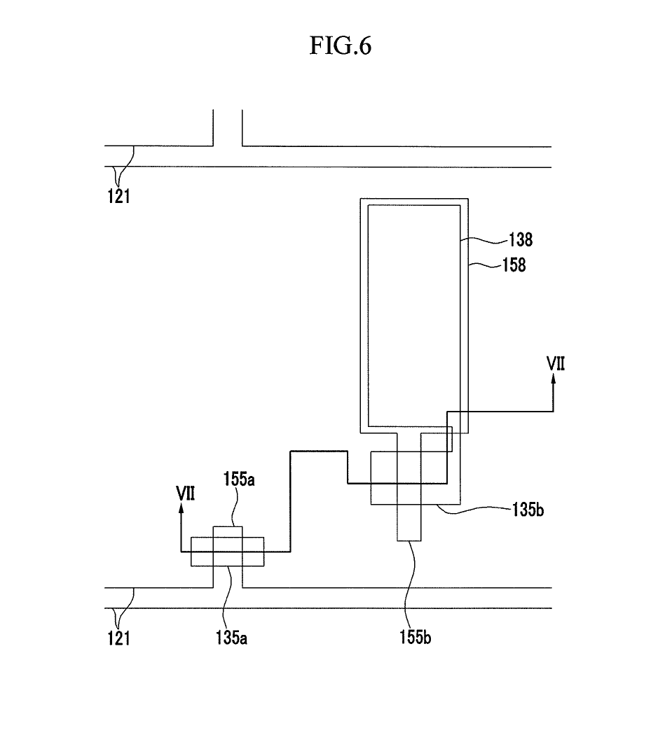

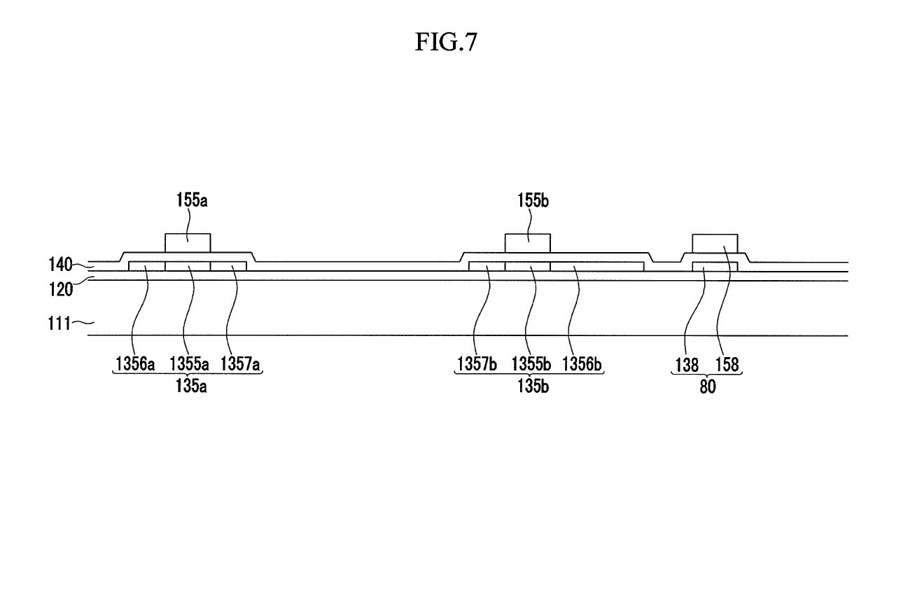

Next, as shown in FIGS. 6 and 7, the gate insulating layer 140 is formed on the first semiconductor 135a and the second semiconductor 135b. The gate insulating layer 140 can be made of silicon nitride (SiNx) or silicon oxide (SiO₂).

Furthermore, after stacking a metal film on the gate insulating layer 140, the first and the second gate electrodes 155a and 155b and the second capacitor electrode 158 are formed by patterning the metal film.

The source region, the drain region, and the channel region are formed by doping conductive impurities into the first semiconductor 135a and the second semiconductor 135b using the first gate electrode 155a and the second gate electrode 155b as masks. In some embodiments, prior to the formation of the first gate electrode 155a and the second gate electrode 155b, the conductive impurities can also be doped into the first capacitor electrode 138 using a photoresist film. Furthermore, if each of the first gate electrode 155a and the second gate electrode 155b is formed of a dual layer and the second capacitor electrode 158 is formed of a single layer, the conductive impurities can also be doped into the first capacitor electrode 138 along with the source region and the drain region.

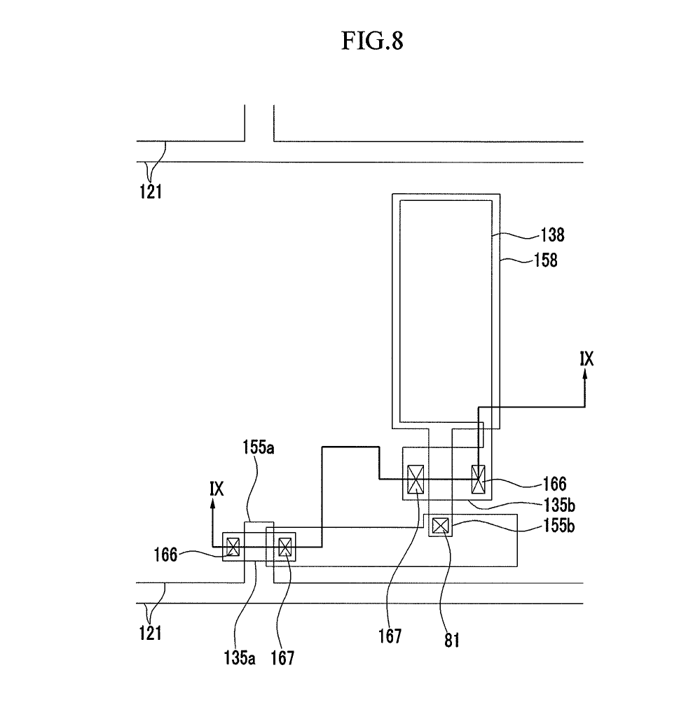

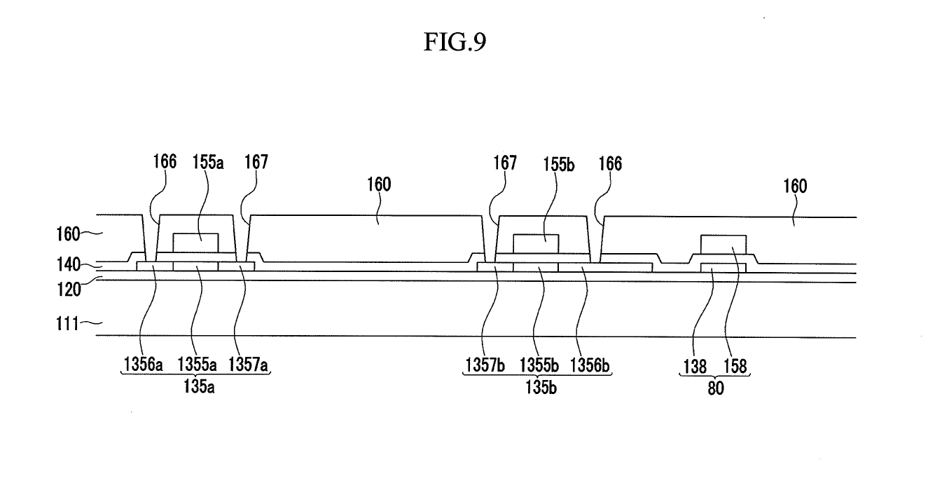

As shown in FIGS. 8 and 9, the interlayer insulating layer 160 having the contact holes 166 and 167 through which the source region and the drain region are exposed is formed on the first and the second gate electrodes 155a and 155b and the second capacitor electrode 158. The interlayer insulating layer 160 can be made of tetra ethyl ortho silicate (TEOS), silicon nitride (SiNx), or silicon oxide (SiO₂). Furthermore, the interlayer insulating layer 160 can be made of a low dielectric constant material and may provide a flat surface.

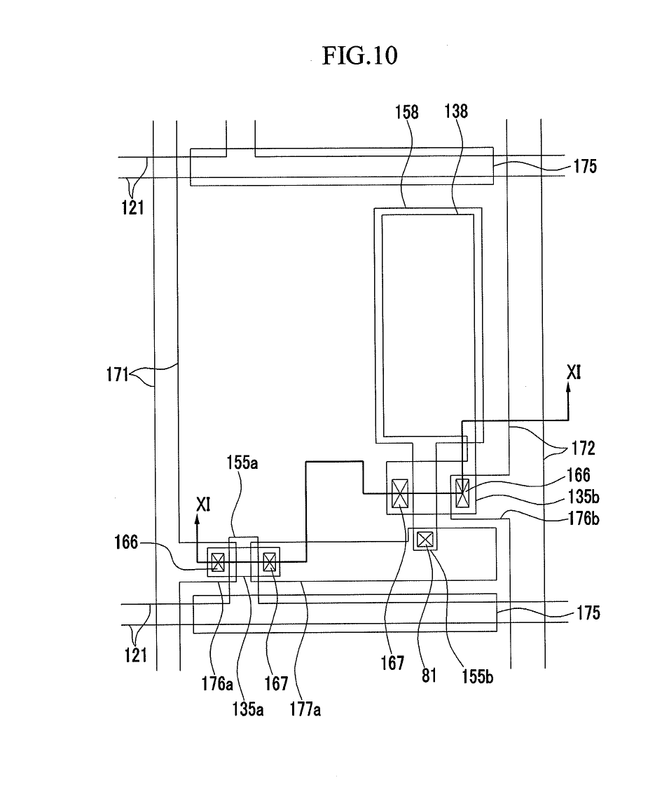

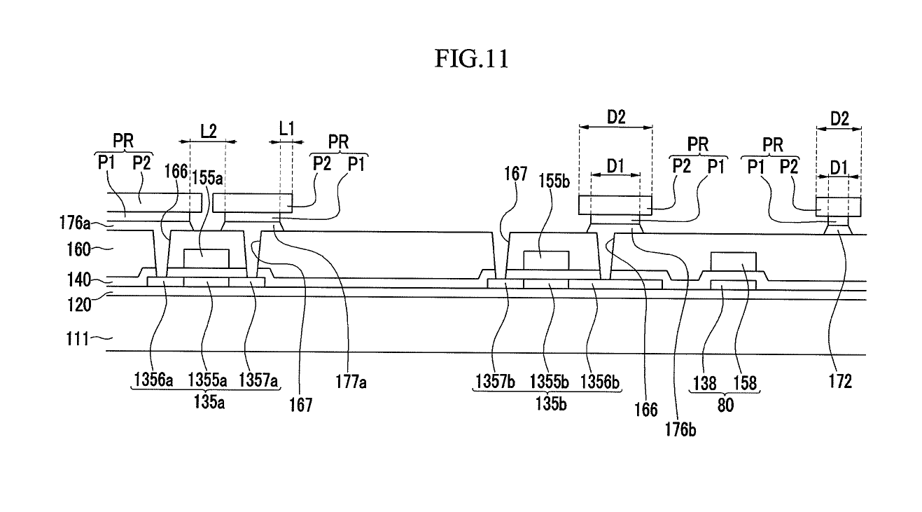

Next, as shown in FIGS. 10 and 11, a metal film is formed on the interlayer insulating layer 160, and a photoresist pattern PR is formed on the metal film. The metal film can be a triple film including Ti, Al, and Ti.

The photoresist pattern PR includes a first part P1 and a second part P2 having different widths. The photoresist pattern can have a T form because a width D1 of the first part P1 is smaller than a width D2 of the second part P2. That is, the photoresist pattern can have an inverse taper structure having a width reduced from the second part P2 to the first part P1.

The photoresist pattern PR having this form can be formed by stacking two photoresist materials having different development speeds. That is, a lower photoresist film is made of material having a fast development speed, and an upper photoresist film having a development speed slower than the lower photoresist film is stacked on the lower photoresist film. Next, the upper photoresist film is exposed and developed in a desired pattern using a photo mask. Here, since the two photoresist films are stacked having different development speeds, the lower photoresist film having a faster development speed than the upper photoresist film is excessively developed, thereby forming the photoresist pattern PR having the different widths D1 and D2.

A difference between the development speeds of the lower photoresist film and the upper photoresist film ca be 2 μm/mim to 10 μm/mim. A distance L1 between one boundary line of the second part P2 and one boundary line of the first part P1 neighboring the second part P2 can be 1 μm or higher.

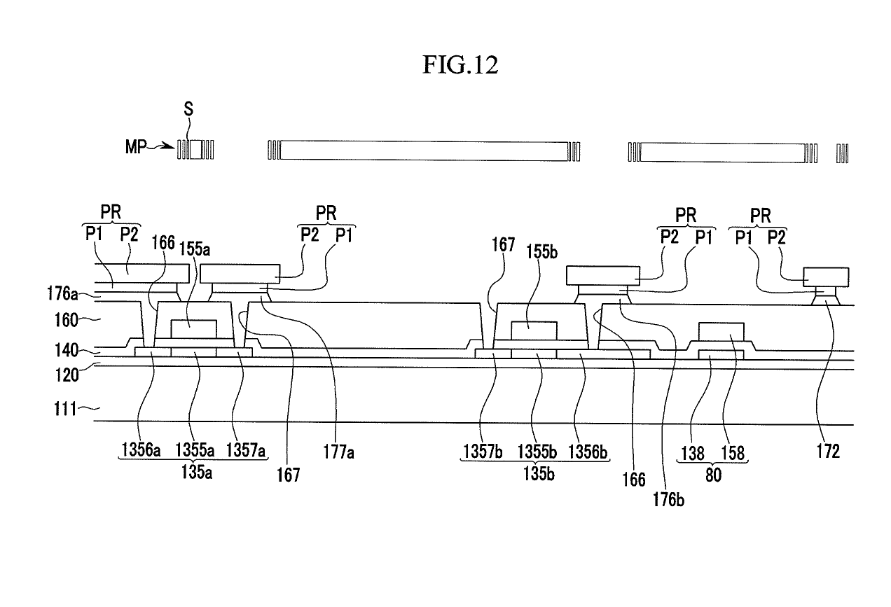

Furthermore, as shown in FIG. 12, the photoresist pattern PR can be made of a negative photoresist material. That is, a photoresist film made of a negative photoresist material is formed on a metal film and then exposed using a photo mask MP having slits S or half-tones. In the photoresist film made of the negative photoresist material, the exposed parts remain intact and parts not exposed are removed when development is performed. Accordingly, since a part corresponding to the half-tone mask is not fully exposed up to the bottom, the bottom not exposed is removed when the development is performed. As a result, the photoresist patterns having different widths are formed.

Next, the data line 171, the constant voltage line 172, the first drain electrode 177a, and the dummy pattern 175 are formed by etching the metal film using the photoresist patterns PR as a mask.

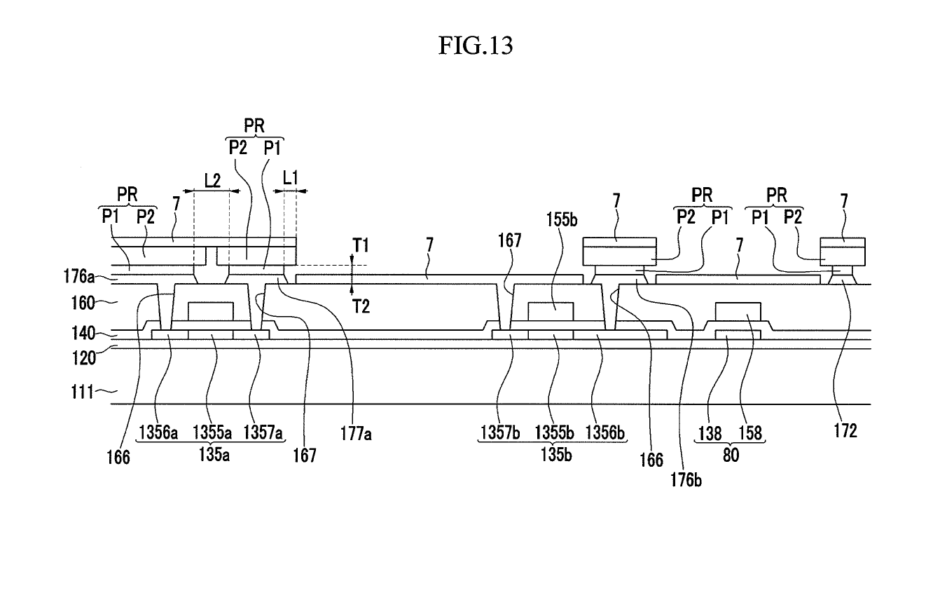

Next, as shown in FIG. 13, a metal film 7 is formed by depositing metal on the substrate 111 including the photoresist patterns PR and the interlayer insulating layer 160. The metal film 7 can be a triple film including ITO, Ag, and ITO.

Here, the photoresist pattern PR forms an undercut because it has different widths. Thus, the metal film 7 can be broken without being connected along the sidewalls of the photoresist pattern PR.

The metal film 7 preferably has a thickness smaller than the sum of the thickness T1 of the first part P1 and the thickness T2 of the data line 171, the constant voltage line 172, the first drain electrode 177a, or the dummy pattern 175 so that the metal film 7 can be easily broken without being connected along the sidewalls of the photoresist pattern PR.

Meanwhile, the first interval L1 between the data line 171, the constant voltage line 172, the first drain electrode 177a, and the dummy pattern 175 and the first electrode 710 can be smaller than the second interval L2 between the data line 171, the constant voltage line 172, the first drain electrode 177a, and the dummy pattern 175.

That is, since the first electrode 710 is broken by the photoresist pattern PR, the first interval L1 corresponds to a distance between one boundary line of the second part P2 and one boundary line of the first part P1 neighboring the second part P2.

In contrast, the second interval L2 between the data line 171, the constant voltage line 172, the first drain electrode 177a, and the dummy pattern 175 is at least two times greater than the first interval L1 because the photoresist patterns PR for forming the data line 171, the constant voltage line 172, the first drain electrode 177a, and the dummy pattern 175 are adjacent to each other.

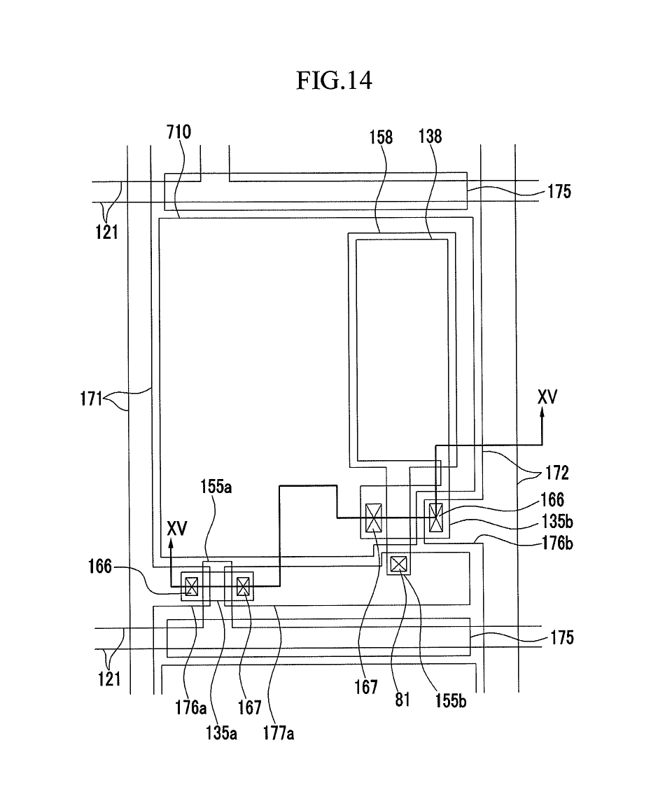

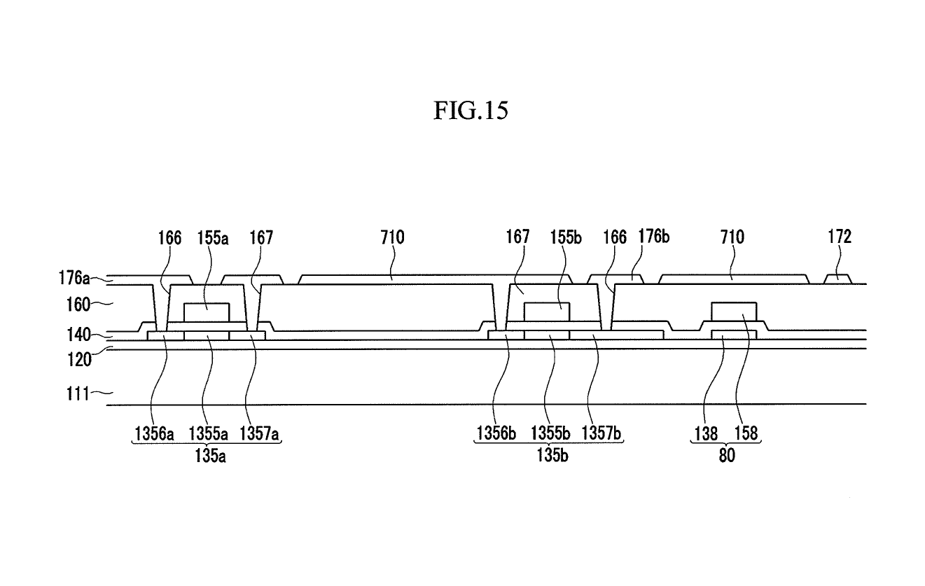

Next, as shown in FIGS. 14 and 15, the first electrode 710 is formed by removing the photoresist patterns PR and the metal films on the photoresist patterns PR, e.g., using a lift-off method.

Since the first electrode 710 has to be separated for each pixel, the dummy pattern 175 is formed so that the first electrode 710 is separated into both sides on the basis of the dummy pattern 175.

The dummy pattern 175 can be formed to overlap with the gate line 121 so that the aperture ratio of the pixel is not reduced.

Meanwhile, since the first interval L1 is 1 μm or higher as shown in FIG. 11, the first electrode 710, the data line 171, the constant voltage line 172, the first drain electrode 177a, and the dummy pattern 175 are not short-circuited although they are formed on the interlayer insulating layer 160.

If the photoresist pattern PR having different widths is used as in an exemplary embodiment, the first electrode 710 and the data line 171 having different characteristics can be formed by one photolithography process.

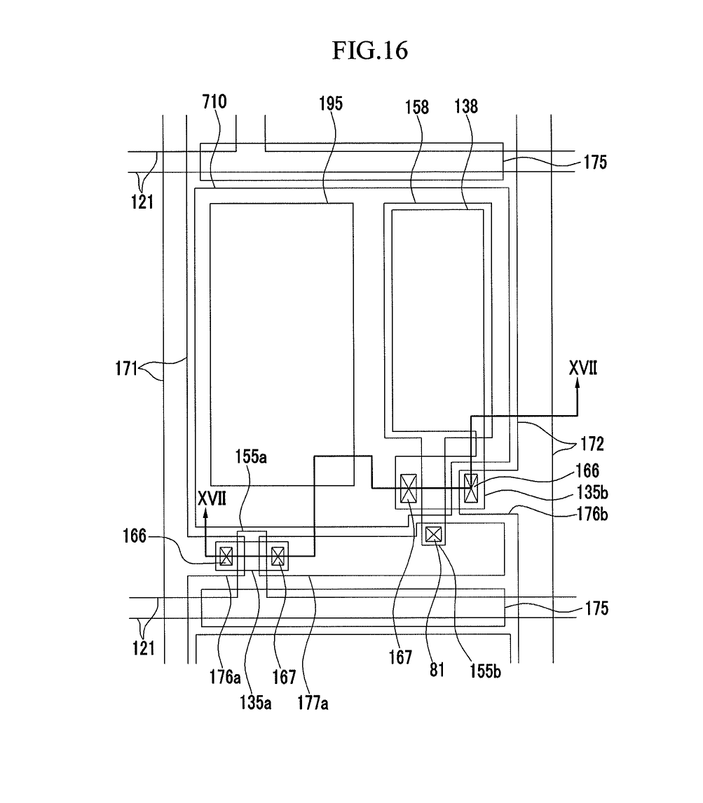

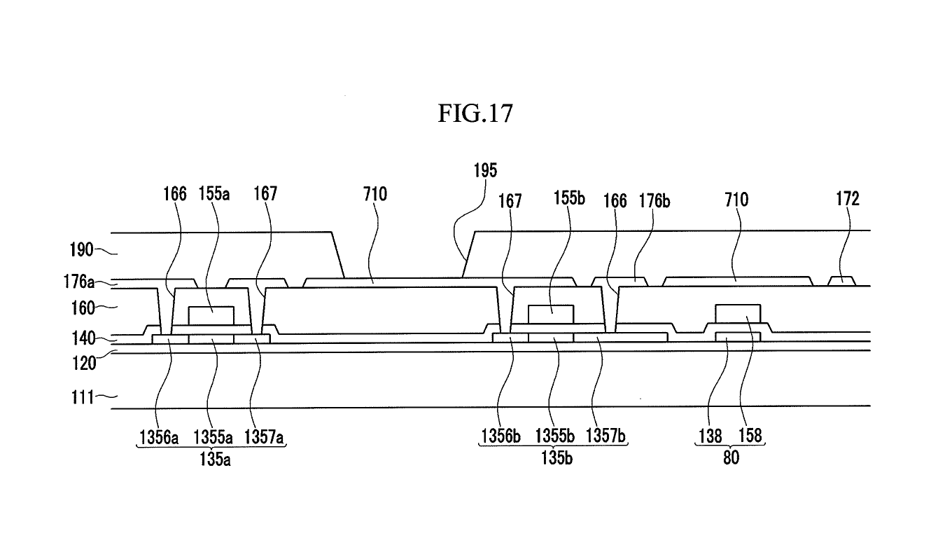

Next, as shown in FIGS. 16 and 17, the pixel definition film 190 having the opening 195 is formed on the first electrode 710, the data line 171, and the constant voltage line 172.

Next, as shown in FIGS. 2 and 3, the organic emission layer 720 is formed in the opening 195 of the pixel definition film 190, and the common electrode 730 is formed on the organic emission layer 720.

By way of summation and review, one or more embodiments provide an organic light emitting diode (OLED) display and a method of manufacturing the same having advantages of increasing the reflectance of an anode electrode and forming a low-resistance data line while not increasing a process of manufacturing the organic light emitting diode (OLED) display.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display, comprising:
a substrate;
a first signal line on the substrate;
a first thin film transistor connected to the first signal line;
a second thin film transistor connected to the first thin film transistor;
an interlayer insulating layer on the first thin film transistor and the second thin film transistor;
a second signal line on the interlayer insulating layer and connected to a source electrode of the first thin film transistor;
a third signal line on the interlayer insulating layer and connected to a source electrode of the second thin film transistor;
a first electrode on the interlayer insulating layer and connected to a drain electrode of the second thin film transistor;
an organic emission layer on the first electrode; and
a second electrode placed on the organic emission layer,
wherein the third signal line and the first electrode are made of different metals.

2. The organic light emitting diode (OLED) display of claim 1, wherein:
the third signal line is made of an identical material with the source electrode of the second thin film transistor, and
the drain electrode of the second thin film transistor and the first electrode are made of an identical material.

3. The organic light emitting diode (OLED) display of claim 2, wherein:
the third signal line is integrally formed with the source electrode of the second thin film transistor and is connected to a semiconductor of the second thin film transistor through a contact hole of the interlayer insulating layer, and
the drain electrode of the second thin film transistor is integrally formed with the first electrode and is connected to the semiconductor of the second thin film transistor through the contact hole of the interlayer insulating layer.

4. The organic light emitting diode (OLED) display of claim 2, wherein:
the third signal line includes metal having a lower resistance than the first electrode, and
the first electrode includes metal having a higher reflectance than the third signal line.

5. The organic light emitting diode (OLED) display of claim 4, wherein:
the metal having the lower resistance include at least one of aluminum, titanium, molybdenum, and an alloy thereof, and
the metal having the higher reflectance is silver.

6. The organic light emitting diode (OLED) display of claim 5, wherein:
the third signal line includes titanium, aluminum, and titanium, and
the first electrode includes ITO, Ag, and ITO.

7. The organic light emitting diode (OLED) display of claim 1, further comprising a dummy pattern on the interlayer insulating layer, the dummy pattern extending in a direction to intersect the second signal line and being separated from the second signal line and the third signal line.

8. The organic light emitting diode (OLED) display of claim 7, wherein the dummy pattern is made of an identical material with the second signal line and the third signal line.

9. The organic light emitting diode (OLED) display of claim 7, wherein a distance between the dummy pattern, the second signal line, the third signal line, the source electrode and drain electrode of the first thin film transistor, the source electrode of the second thin film transistor, and the first electrode is smaller than a distance between the dummy pattern, the second signal line, the third signal line, the source electrode and drain electrode of the first thin film transistor, and the source electrode of the second thin film transistor.

10. A method of manufacturing an organic light emitting diode (OLED) display, comprising:
forming a first signal line on a substrate;
forming a thin film transistor connected to the first signal line;
forming an interlayer insulating layer on the thin film transistor;
forming a first metal film on the interlayer insulating layer;
forming photoresist patterns over the first metal film, each photoresist pattern including a first part having a first width and a second part have a second width wider than the first width, the second part being on the first part;
forming a second signal line by etching the first metal film using the photoresist patterns as a mask;
forming a first electrode on the interlayer insulating layer;
forming an organic emission layer on the first electrode; and
forming a second electrode on the organic emission layer.

11. The method of claim 10, wherein the first part and the second part are made of different photoresist materials.

12. The method of claim 11, wherein forming the photoresist patterns includes:
stacking a first photoresist film and a second photoresist film, having different development speeds, on the first metal film; and
developing the first photoresist film and the second photoresist film.

13. The method of claim 12, wherein the development speed of the first photoresist film is faster than the development speed of the second photoresist film.

14. The method of claim 10, wherein forming the photoresist patterns includes:
forming a photoresist film on the first metal film using a negative photoresist material; and
exposing the photoresist film using the photoresist film by a half-tone mask and then developing the photoresist film.

15. The method of claim 10, wherein forming the first electrode includes forming a second metal film over the photoresist patterns and the interlayer insulating layer and then removing the photoresist patterns using a lift-off method.

16. The method of claim 10, further comprising forming a third signal line on the interlayer insulating layer, wherein the third signal line and the first electrode are made of different materials.

17. The method of claim 16, further comprising forming a dummy pattern on the interlayer insulating layer, the dummy pattern extending in a direction to intersect the second signal line and being separated from the second signal line and the third signal line.
